(19) United States
(12) Patent Application Publication
(10) Pub. No.: US 2011/0012613 A1
(43) Pub. Date: Jan. 20, 2011

(54) Failure Detection Method and Failure Detection Apparatus

(75) Inventors: Bin Gong, Shanghai (CN); Qiang Guo, Shanghai (CN)

Correspondence Address: SQUIRE, SANDERS & DEMPSEY L.L.P., 275 BATTERY STREET, SUITE 2600, SAN FRANCISCO, CA, 94111-3356, US

(73) Assignee: Semiconductor Manufacturing International (Shanghai) Corporation, Shanghai (CN)

(21) Appl. No.: 12/836,093

(22) Filed: Jul. 14, 2010

(30) Foreign Application Priority Data
Jul. 16, 2009 (CN) 200910054951.6

(51) Int. Cl. G01R 31/02

(52) U.S. Cl. 324/543

(57) ABSTRACT

The present invention discloses a failure detection method and a failure detection apparatus for detecting a defect in an electrical conductor. The failure detection method includes: providing at least two output terminals on the electrical conductor under test, the at least two output terminals having identical electric potentials; inputting a constant detection current sequentially to detection points arranged on the electrical conductor under test along a predetermined path; detecting an output current at one or more output terminals of the at least two output terminals; building a correspondence relationship between the detected one or more output currents at the one or more output terminals and positions of the detection points, based on information of the positions of the detection points and information of the detected one or more output currents at the one or more output terminals; and determining from the correspondence relationship whether the detection points have a defect. The failure detection method according to the invention can precisely locate defects; and uses a charged particle beam as the detection current source to avoid the size limitation of irradiation points, thereby satisfying the requirement for failure analysis in a small size.

### FIELD OF THE INVENTION

The present invention relates to the field of semiconductor manufacturing, and in particular to a failure detection method and a failure detection apparatus for metal interconnection lines in semiconductor devices.

### BACKGROUND OF THE INVENTION

In the field of semiconductor manufacturing, failure analysis of semiconductor devices is a feedback procedure to improve reliability and stability of the manufacturing process, including finding and correcting the causes of defects to overcome problems resulting from the defects. Proper failure analysis is crucial in quality improvement of semiconductor devices. And improper failure analysis may prolong the cycle time it takes to develop and improve semiconductor device products. Failure analysis generally includes external examination, non-destructive analysis, electrical verification, destructive analysis, etc.

To improve the level of integration of a semiconductor device, it is desired to obtain as many elements as possible in a limited area, which further leads to increased complexity of the semiconductor device. Therefore, accurate analysis of the cause of a failure may not be possible by external examination or electrical performance detection alone, consequently, direct exposure of internal structure of the semiconductor device would be necessary for the study of failures.

As the linewidth shrinks to the 45-nanometer level, defects in metal interconnection lines may severely affect the performance of devices. Even a tiny defect may make a device completely useless. Therefore, failure analysis of internal metal interconnection lines is very important. Generally speaking, defects in metal interconnection lines include voids, particles, etc.

In the field of semiconductors, an existing method for failure analysis of chips is Optical Beam Induced Resistance Change (OBIRCH), which performs fault isolation using laser scanning techniques. Its general principle is illustrated in FIG. 1. An external DC voltage is applied between an input terminal 2 and an output terminal 3 of a device under test 1, and a laser beam scans an internal connection node 4 of the device, where functional regions or elements in the device are connected. Then the temperature varies due to the thermal effect of the laser, thereby causing a resistance change at the connection node 4, which further leads to a current change at the output terminal 3. The trend of the output current change is recorded, and compared with an output current change of a product without any defects under the same test, to locate the defect causing a failure. By using this method, the area where a defect is can be quickly located in a semiconductor device, and the defects can further be located precisely by repeating the test multiple times and narrowing down the range of the defect.

However, OBIRCH is only suitable for large-range defect locating for semiconductor devices, fails to meet the requirement for failure analysis in a small size, and suffers from poor electrical sensitivity for defect detection and low spatial resolution due to the spot size limited by the optical imaging system especially when the defect detection is performed on narrowly sized metal interconnection lines.

### SUMMARY OF THE INVENTION

A technical problem solved by the invention is to provide a failure detection method and a failure detection apparatus, for locating defects in metal interconnection lines in semiconductor devices, and suitable for failure analysis in a small size.

To address the above issue, an embodiment of the invention provides a failure detection method for detecting a defect in an electrical conductor, including:
providing at least two output terminals on the electrical conductor under test, the at least two output terminals having identical electric potentials;
inputting a constant detection current sequentially to detection points arranged on the electrical conductor under test along a predetermined path;
detecting an output current at one or more output terminals of the at least two output terminals;
building a correspondence relationship between the detected one or more output currents at the one or more output terminals and positions of the detection points, based on information of the positions of the detection points and information of the detected one or more output currents at the one or more output terminals; and
determining from the correspondence relationship whether the detection points have a defect.

Further, an embodiment of the invention provides a failure detection method for detecting a defect in a wire, including:
providing an output terminal at both ends of the wire, the output terminals having identical electric potentials;
inputting a constant detection current sequentially to detection points arranged on the wire along a predetermined path;
detecting an output current at one or both of the output terminals;
building a correspondence relationship between the detected one or both output currents at the one or both of the output terminals and positions of the detection points, based on information of the positions of the detection points and information of the detected one or both output currents at the one or both of the output terminals; and
determining from the correspondence relationship whether the detection points have a defect.

Based on the failure detection method above, an embodiment of the invention provides a failure detection apparatus for detecting a defect in an electrical conductor under test, the electrical conductor being provided with at least two output terminals and the output terminals having identical electric potentials. The failure detection apparatus includes:
a detection current input module, adapted to input a detection current sequentially to detection points arranged on the electrical conductor under test along a predetermined path;
an output current detection module, adapted to detect an output current at one or more output terminals of the at least two output terminals; and
an analysis module, adapted to build a correspondence relationship between the detected one or more output currents at the one or more output terminals and positions of the detection points, based on information of the positions of the detection points and information of the detected one or more output currents at the one or more output terminals, to perform failure detection on the electrical conductor under test.

Compared with the prior art, the failure detection method provided by the invention uses detection points as input terminals for a direction current, and analyzes output currents at multiple output terminals, thereby achieving precise location of defects; and uses a charged particle beam as the detection current source to avoid the size limitation of irradiation points and the thermal effect, thereby satisfying the requirement for failure analysis in a small size and protecting the device under test from being damaged.

### BRIEF DESCRIPTION OF THE DRAWINGS

The above and other objects, characteristics and advantages of the invention will become more apparent from the following detailed descriptions of preferred embodiments thereof as illustrated in the drawings. Components in the drawings the same as those in the prior art are denoted with identical reference numerals. The drawings are not necessarily drawn to scale but highlight the essence of the invention. For clarity, relevant structures are exaggerated in size in the drawings:

FIG. 1 is a diagram illustrating the principle of failure analysis using OBIRCH in the prior art;

FIG. 2 illustrates a flow chart of a failure detection method according to the invention;

FIG. 3 illustrates a flow chart of another failure detection method according to the invention;

FIG. 4 is a diagram illustrating the principle of a first embodiment of a failure detection method according to the invention;

FIG. 5 is a diagram illustrating an equivalent circuit of the first embodiment of the failure detection method according to the invention;

FIG. 6 illustrates a curve showing the relationship between currents at output terminals and positions of detection points according to the first embodiment of the invention;

FIG. 7 is a diagram illustrating the principle of a second embodiment of a failure detection method according to the invention;

FIG. 8 is a diagram illustrating an equivalent circuit of the second embodiment of the failure detection method according to the invention;

FIG. 9 illustrates a curve showing the relationship between currents at output terminals and positions of detection points according to the second embodiment of the invention; and

FIG. 10 illustrates a schematic diagram of a failure detection device according to an embodiment of the invention.

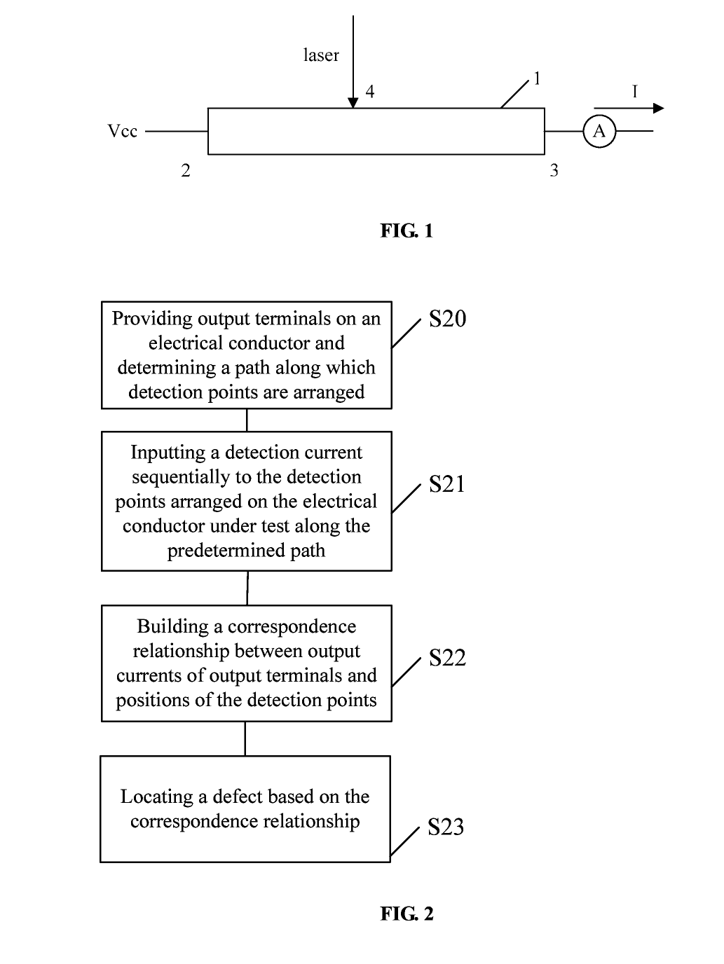

### DETAILED DESCRIPTION OF THE INVENTION

According to the law of charge conservation, the total output current from a device is equal to the total input current. Therefore, if we place some output terminals having identical electric potentials on an electrical conductor (i.e., these output terminals are at the same electric potential), and input a detection current to the electrical conductor, the sum of currents at the output terminals is a fixed value. Because currents always flow along the path with the minimum resistance, the magnitudes of the currents at the output terminals depend on the resistances between the output terminals and the detection point. As the detection point changes its position, the magnitudes of the currents at the output terminals vary correspondingly in a fixed relationship, that is, if the same detection current is input at a fixed detection point, the output currents at the output terminals are fixed, and form a correspondence relationship with the position of the detection point. If a defect occurs at the detection point or adjacent to the detection point, under the same input detection current, the output currents at the output terminals vary, so does the correspondence relationship.

Based on the principle discussed above, according to characteristics of an electrical conductor under test, a failure detection method is provided below.

Reference is made to in FIG. 2 illustrating a flow chart of a failure detection method according to the invention, which includes the following steps.

S20. At least two output terminals are provided on an electrical conductor under test, and the output terminals have identical electric potentials; and a path along which detection points are arranged on the electrical conductor under test is predetermined.

Preferably, the output terminals are distributed on the electrical conductor under test as uniformly as possible.

S21. A constant detection current is input sequentially to the detection points arranged on the electrical conductor under test along the predetermined path.

Preferably, a beam of charged particles with a constant energy may be used as the detection current source to irradiate the detection points, and the beam of charged particles may be an electron beam or an ion beam.

S22. Output currents at the output terminals are detected; and a correspondence relationship between the output currents at the output terminals and positions of the detection points is built, based on information of the positions of the detection points and information of the output currents at the output terminals.

The correspondence relationship may be a curve of the magnitude, the rate of change or the like of an output current at one of the output terminals versus the positions of the detection points. Alternatively, the correspondence relationship may be a curve of a difference, a ratio, or the like between output currents at some of the output terminals versus the positions of the detection points. The correspondence relationship may also be determined according to actual needs such as whether it is easy to be expressed, whether the data collection can be done easily, etc.

S23. It is determined from the correspondence relationship whether the detection points have a defect.

Criteria for the determination are given below.

For an electrical conductor uniformly shaped and with a smooth transition, if no defect is present at a detection point or adjacent to the detection point, the correspondence relationship shall have a regular variation when the position of the detection point is moved along the predetermined movement path, and if the correspondence relationship varies irregularly at a detection point, we determine that a defect is present at the detection point or adjacent to the detection point.

For an electrical conductor having a sudden change in its shape or material, when the position of the detection point is moved along the predetermined movement path, the correspondence relationship shall also have a regular variation except at where the shape or material takes the known sudden change, and if the correspondence relationship varies irregularly at a detection point without the sudden change of shape or material, we determine that a defect is present at the detection point or adjacent to the detection point.

Moreover, the scenarios above may further be simplified if the electrical conductor under test is a wire. For a one-dimension wire, we may simply place grounded output terminals at both ends of the wire, and when the position of the detection point is moved along the wire while keeping the input detection current constant, the correspondence relationship of output currents at the two output terminals versus the position of the detection point shall have a substantially linear variation assuming that no defect is present in the wire, as derived in the following embodiment. If the correspondence relationship varies irregularly, we determine that a defect is present at the detection point or adjacent to the detection point.

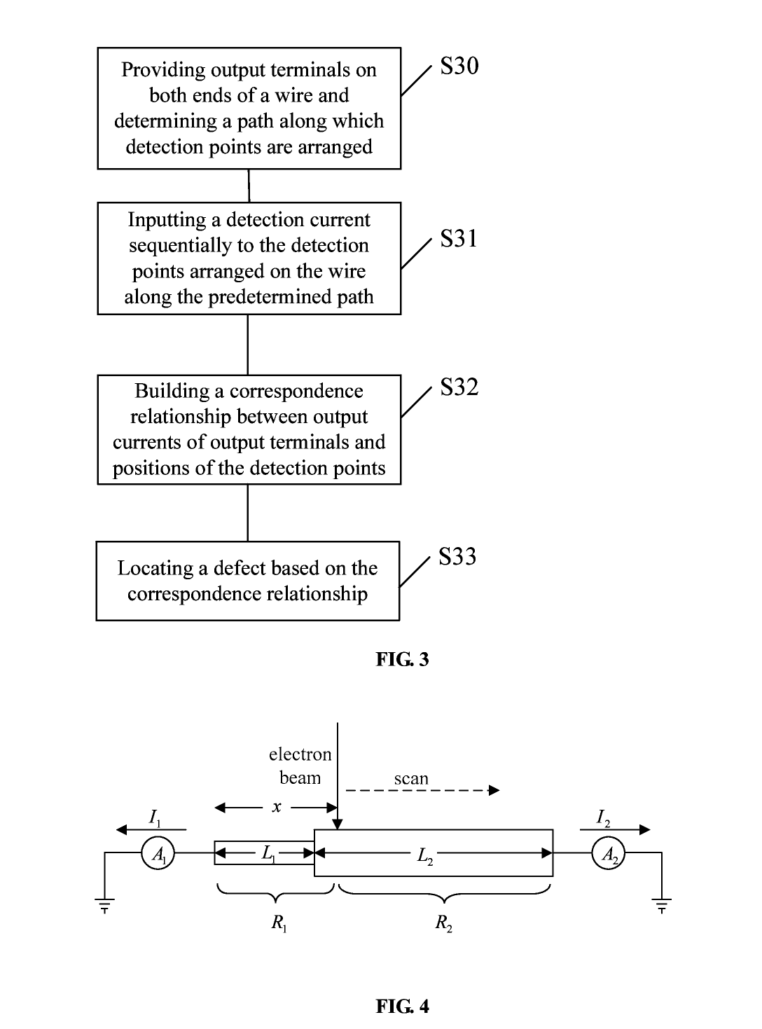

Based on the above principle above, reference is made to in FIG. 3 illustrating a flow chart of another failure detection method according to the invention, which includes the following steps.

S30. Output terminals are provided at both ends of a wire, and the output terminals have identical electric potentials; and a path along which detection points are arranged on the wire is determined in advance. Preferably, both ends of the wire may be grounded directly, and the path along which the detection points are arranged may run from one end of the wire to the other end.

S31. A constant detection current is input sequentially to the detection points arranged on the wire along the predetermined path.

Preferably, a beam of charged particles with a constant energy may be used as the detection current source to irradiate the detection points, and the beam of charged particles may be an electron beam or an ion beam.

S32. Output currents at the output terminals are detected; and a correspondence relationship between the output currents at the output terminals and positions of the detection points is built based on information of the positions of the detection points and information of the output currents at the output terminals;

What the correspondence relationship is may be determined based on actual needs, which is omitted here, reference can be made to the failure detection method discussed above.

S33. It is determined from the correspondence relationship whether the detection points have a defect.

Criteria for the determination are given below:

If no defect is present at a detection point or adjacent to the detection point, the correspondence relationship shall have a linear variation when the position of the detection point is moved along the predetermined movement path, and if the correspondence relationship varies irregularly at a detection point, we determine that a defect is present at the detection point or adjacent to the detection point.

The two failure detection methods above are addressed for different failure detection requirements, and may be used individually or collectively according to actual situation of the device under test. For failure analysis in the field of semiconductors, e.g., the methods above can be used in combination due to the complexity of electrically conductive layers, interconnection lines, elements and the like in the semiconductor structure. For failure analysis for a specific semiconductor structure, we may first detect regional nodes, then interconnection lines, and finally elements, narrowing down the range of the defect step by step, thereby improving accuracy of failure detection and efficiency of failure analysis.

The failure detection methods above will be further described hereinafter in connection with the following embodiments.

Reference is made to FIG. 4, a diagram illustrating a first embodiment of the failure detection method according to the invention.

Particularly, the electrical conductor under test is a metal plate uniform in material but irregular in shape. For simplicity, we assume the metal plate has a total length of L, consisting two parts with different thicknesses, one having a length of L₁ and a cross-sectional area of S₁ and the other one having a length of L₂ (L₂=L−L₁) and a cross-sectional area of S₂; and we assume the metal plate has a resistivity of ρ. Two ends of the metal plate are grounded via a current meter A₁ and a current meter A₂, respectively.

In failure detection, the metal plate is irradiated with a beam of charged particles with a constant energy, and is scanned along a predetermined movement path, while recording the change of output currents at the two output terminals and corresponding irradiation positions of the beam of charged particles. The beam of charged particles is equivalent to a constant current source having a current of I; the output currents recorded by the current meters A1 and A2 at the two output terminals are I₁ and I₂, respectively; distance from the irradiation point, i.e., the detection point, to an end of the metal interconnection line connected with the current meter A₁ is x; and the metal interconnection line is divided by the detection point into a left part having a length of x and a resistance of R₁, and a right part having a length of L−x and a resistance of R₂.

Suppose the metal plate has a relatively large aspect ratio, which makes it possible to compare it to a one-dimension conductor, therefore we have:

The metal plate has a resistance per unit length of:

$${ρ}_{l} = ρ / S ;$$

$${R}_{1} = \{ \begin{matrix}{\int }_{0}^{x} {ρ}_{l} ( x ) d x = {\int }_{0}^{x} ρ ( x ) / {S}_{1} d x ( x \leq {L}_{1} ) \\ {\int }_{0}^{x} {ρ}_{l} ( x ) d x = ρ {L}_{1} / {S}_{1} + {\int }_{{L}_{1}}^{x} ρ ( x - {L}_{1} ) / {S}_{2} d x ( L > x > {L}_{1} ) ;\end{matrix} \\ {R}_{2} = \{ \begin{matrix}{\int }_{0}^{x} {ρ}_{l} ( x ) d x = {\int }_{x}^{{L}_{1}} ρ ( x ) / {S}_{1} d x + ρ ( L - {L}_{1} ) / {S}_{2} ( x \leq {L}_{1} ) \\ {\int }_{0}^{x} {ρ}_{l} ( x ) d x = {\int }_{{x}_{1}}^{L} ρ ( L - x ) / {S}_{2} d x ( L > x > {L}_{1} ) ;\end{matrix} \\ {R}_{1} + {R}_{2} = ρ {L}_{1} / {S}_{1} + ρ ( L - {L}_{1} ) / {S}_{2} = R ;$$

where R represents the total resistance of the metal plate.

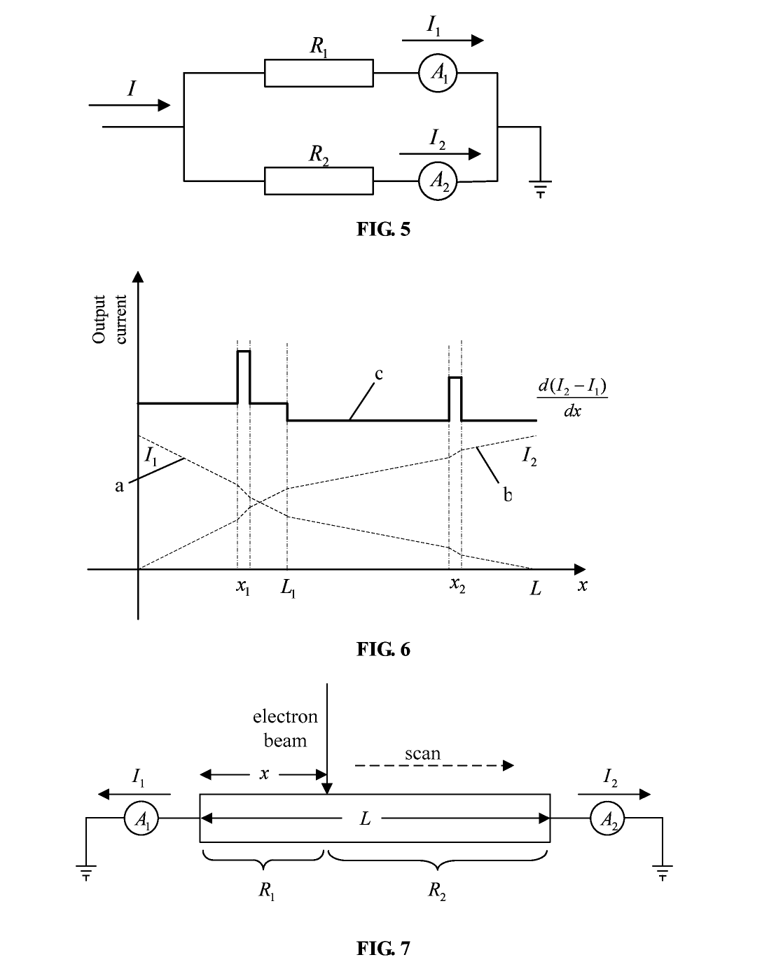

Reference is made to FIG. 5 illustrating an equivalent circuit of the above embodiment, that is, it is equivalent to connect the two parts of the metal plate in parallel and use the detection point as an input terminal to input the current I, and we have:

$${I}_{1} = \frac{{R}_{2}}{R} I$$

$${I}_{2} = \frac{{R}_{1}}{R} I ;$$

Assuming that the end of the metal plate connected with the current meter A₁ is the origin, the positional coordinate of the detection point is x; and combining the equations above, we derive the following equations about the output currents I₁ and I₂ versus the positional coordinate x of the detection point:

$$\frac{d {I}_{1}}{d x} = \frac{I}{R} \frac{d {R}_{2}}{d x} = \{ \begin{matrix}- \frac{I}{R} ρ ( x ) / {S}_{1} ; ( x \leq {L}_{1} ) \\ - \frac{I}{R} ρ ( x ) / {S}_{2} ; ( L > x > {L}_{1} )\end{matrix} \\ \frac{d {I}_{2}}{d x} = \frac{I}{R} \frac{d {R}_{1}}{d x} = \{ \begin{matrix}\frac{I}{R} ρ ( x ) / {S}_{1} ; ( x \leq {L}_{1} ) \\ \frac{I}{R} ρ ( x ) / {S}_{2} ; ( L > x > {L}_{1} )\end{matrix} \\ \frac{d ( {I}_{2} - {I}_{1} )}{d x} = \frac{I}{R} \frac{d ( {R}_{1} - {R}_{2} )}{d x} = \{ \begin{matrix}\frac{2 I}{R} ρ ( x ) / {S}_{1} ; ( x \leq {L}_{1} ) \\ \frac{2 I}{R} ρ ( x ) / {S}_{1} ; ( L > x > {L}_{1} ) ;\end{matrix}$$

Reflecting the equations above on the curves, we derive the correspondence relationship between the output currents at the two output terminals and the position of the detection point. The correspondence curves a and b are curves of the magnitudes of the currents at the two output terminals versus the coordinate of the detection point, respectively. The correspondence curve c is a curve of the rate of change of the difference between the currents at the two output terminals versus the coordinate of the detection point. According to the equations above, these curves are section curves, with the correspondence curves a and b have slopes of

$$\frac{d {I}_{1}}{d x} and \frac{d {I}_{2}}{d x} ,$$

and the correspondence curve c has a curve function of

$$\frac{d ( {I}_{2} - {I}_{1} )}{d x} .$$

Assuming defects are present at two coordinates x₁ and x₂ on the metal plate, which causes the resistivity there to be only ρ/2, i.e., half of that the resistivity of normal parts of the metal plate. Therefore, when the metal plate is scanned by the beam of charged particles from one end of the metal plate to the other end along a predetermined path along which the detection point is moved, the curves can be derived as illustrated in FIG. 6.

As can be apparent from FIG. 6, the correspondence curves a, b and c all vary irregularly at the three coordinates x₁, L₁ and x₂, and as can be derived from the above equations, the slopes of respective curves at x₁ and x₂ are twice as those in a normal case. We know that L₁ is where the sudden change in shape of the metal plate, therefore the corresponding irregular variation of the curves at L₁ shall be excluded. Hence, the specific location of a defect can be detected easily and intuitively with the failure detection method according to the embodiment of the invention.

It shall be noted that, in this embodiment the correspondence curves a, b and c represent the correspondence relationships of the output current I₁, the output current I₂, and the rate of change of the difference (I₂−I₁) versus the position x of the detection point, respectively; however, in practice, any of the foregoing correspondence relationships may be used, and a corresponding output current may be detected, thereby accomplishing defect detection and finding. It is not necessary to detect at all the output terminals.

Reference is made to FIG. 7 illustrating a second embodiment of the failure detection method according to the invention.

Particularly, an electrical conductor under test is a metal interconnection line of a homogenous medium having a length of L, a cross-sectional area of S and a metal resistivity of ρ, in a semiconductor device. Two ends of the metal interconnection line are grounded via a current meter A₁ and a current meter A₂, respectively.

In failure detection, the metal interconnection line is irradiated with a beam of charged particles with a constant energy, and is scanned along a predetermined movement path, while recording the change of output currents at the two output terminals and corresponding irradiation positions of the beam of charged particles. The beam of charged particles is equivalent to a constant current source having a current of I; the output currents recorded by the current meters A1 and A2 at the two output terminals are I₁ and I₂, respectively; the distance between the irradiation point, i.e., the detection point, and an end of the metal interconnection line connected with the current meter A₁ is x; and the metal interconnection line is divided by the detection point into a left part having a length of x and a resistance of R₁, and a right part having a length of L−x and a resistance of R₂.

Therefore we have:

The metal interconnection line has a resistance per unit length of: ρ_{ι}=ρ/S;

R₁=∫₀^{x}ρ_{ι}(x)dx;

R₂=∫ₓ^{L}ρ_{ι}(x)dx;

R₁+R₂=∫₀^{L}ρ_{ι}(x)dx=R;

where R represents the total resistance of the metal interconnection line.

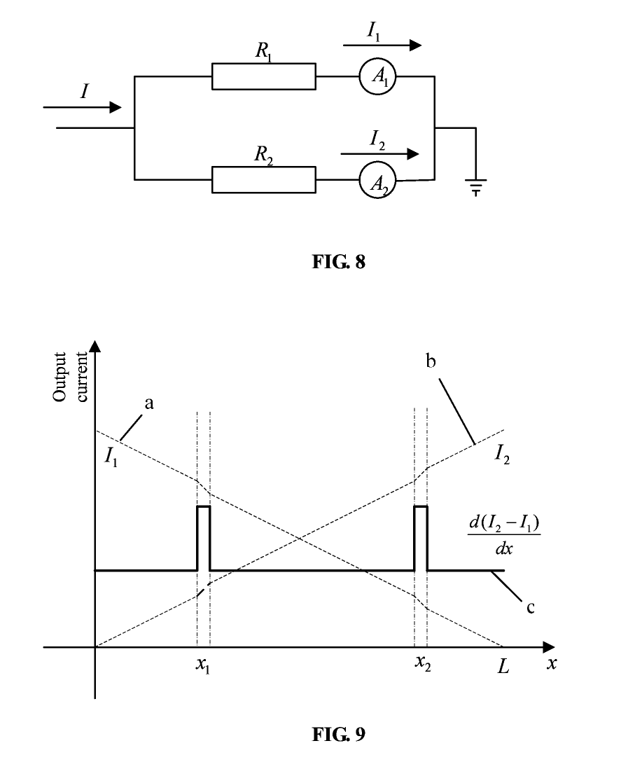

Reference is made to FIG. 8 illustrating an equivalent circuit of the this embodiment, that is, it is equivalent to connect the two parts of the metal interconnection line in parallel and use the detection point as an input terminal to input the current I, and we have:

$${I}_{1} = \frac{{R}_{2}}{R} I$$

$${I}_{2} = \frac{{R}_{1}}{R} I ;$$

Assuming that the end of the metal interconnection line connected with the current meter A₁ is the origin, the positional coordinate of the detection point is x; and combining the equations above, we derive the following equations about the output currents I₁ and I₂ versus the positional coordinate x of the detection point:

$$\frac{d {I}_{1}}{d x} = \frac{I}{R} \frac{d {R}_{2}}{d x} = - \frac{I}{R} {ρ}_{l} ( x )$$

$$\frac{d {I}_{2}}{d x} = \frac{I}{R} \frac{d {R}_{1}}{d x} = - \frac{I}{R} {ρ}_{l} ( x )$$

$$\frac{d ( {I}_{2} - {I}_{1} )}{d x} = \frac{I}{R} \frac{d ( {R}_{1} - {R}_{2} )}{d x} = \frac{2 I}{R} {ρ}_{l} ( x ) ;$$

Reflecting the three equations above on the curves, we derive the correspondence relationship between the output currents at the two output terminals and the position of the detection point. The correspondence curves a and b are curves of the magnitudes of the currents at the two output terminals versus the coordinate of the detection point, respectively. The correspondence curve c is a curve of the rate of change of the difference between the currents at the two output terminals versus the coordinate of the detection point. According to the equations above, the curves are straight lines, with the correspondence curves a and b have slopes of

$$\frac{d {I}_{1}}{d x} and \frac{d {I}_{2}}{d x} ,$$

and the correspondence curve c has a curve function of

$$\frac{d ( {I}_{2} - {I}_{1} )}{d x} .$$

Assuming defects are present at two coordinates x₁ and x₂ on the metal interconnection line, which cause the resistivity there to be only ρ/2, i.e., half of that the resistivity of normal parts of the metal interconnection line. Therefore, when the metal interconnection line is scanned by the beam of charged particles from one end to the other along a predetermined path along which the detection point is moved, the curves can be derived as illustrated in FIG. 9.

As can be apparent from FIG. 9, the correspondence curves a, b and c all vary irregularly at the two coordinates x₁ and x₂, and as can be derived from the above equations, the slopes of respective curves at x₁ and x₂ are twice as those in a normal case. Therefore, the specific location of a defect can be detected easily and intuitively with the failure detection method according to the invention. Similar to the first embodiment, any of the foregoing correspondence relationships represented by the three correspondence curves above may be used, and a corresponding output current may be detected, thereby accomplishing defect detection and finding.

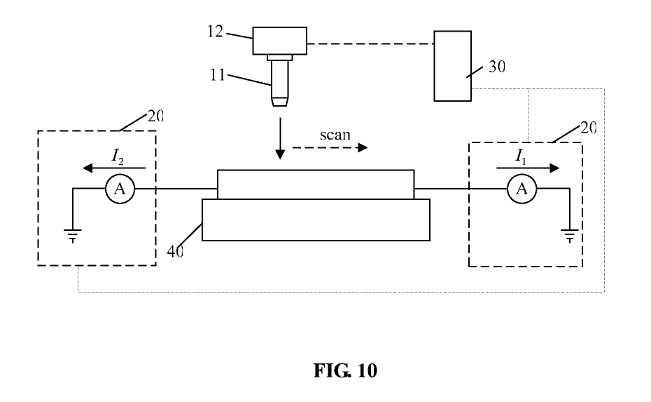

Based on the failure detection methods above, an embodiment of the invention provides a failure detection apparatus, for detecting a defect in an electrical conductor. The electrical conductor is provided with at least two output terminals, the output terminals have identical electric potentials, as illustrated in FIG. 10. The failure detection apparatus mainly includes:
a detection current input module 10, adapted to input a detection current sequentially to detection points arranged on an electrical conductor under test along with a predetermined path;
a plurality of output current detection modules 20, adapted to detect output currents at the output terminals; and
an analysis module 30, adapted to build a correspondence relationship between the output currents at the output terminals and positions of the detection points, based on information of the positions of the detection points and information of the output currents at the output terminals, to perform failure analysis on the electrical conductor under test.

The failure detection device further includes a movement means 12 and a bearing station 40; the movement means 12 is adapted to change a position where the electrical conductor under test is irradiated by a charged particle beam generator; and the bearing station 40 is adapted to bear and fix the electrical conductor under test.

Particularly, the detection current input module includes a charged particle beam emitter 11 which is adapted to generate a beam of charged particles to irradiate the electrical conductor under test.

The moving means 12 may directly align with and move the charged particle beam emitter 11, and the bearing station 40 may be fixed such that the charged particle beam emitter 11 can scan the electrical conductor under test. Alternatively, the charged particle beam emitter 11 may be fixed, and the moving means 12 may drive the bearing station 40 bearing the electrical conductor under test such that the irradiation position of the beam of charged particles can be moved on the electrical conductor under test.

The output current detection modules 20 include a current meter, one end of the current meter is connected with the electrical conductor under test and the other end is connected with a fixed electric potential, e.g., the ground. Since the internal resistance of the current meter is considered to be zero, the output terminals of the electrical conductor are at the same electric potential.

The analysis module 30 may receive the information of the positions of the detection points generated by the movement means 12 and the information of the output currents at the output terminals generated by the output current detection module 20, build the correspondence relationship between the output currents at the output terminals and the positions of the detection points, to perform failure analysis on the electrical conductor under test. Alternatively, the analysis module 30 may generate a scan path, control the movement means 12 in a way such that the electrical conductor under test is irradiated by the charged particle beam emitter 11 along the scan path, and detect the output currents at the output terminals by the output current detection module 20, and build the correspondence relationship between the output currents at the output terminals and the positions of the detection points, to perform failure analysis on the electrical conductor under test.

Preferred embodiments of the invention are disclosed above, however, they are not intended to limit the scope of the appended claims. Those skilled in the art may make alternations and modifications without departing from the spirit and scope of the invention. Accordingly, the scope of the invention should be defined by the claims.

1. A failure detection method for detecting a defect in an electrical conductor, comprising:
providing at least two output terminals on the electrical conductor under test, the at least two output terminals having identical electric potentials;
inputting a constant detection current sequentially to detection points arranged on the electrical conductor under test along a predetermined path;
detecting an output current at one or more output terminals of the at least two output terminals;
building a correspondence relationship between the detected one or more output currents at the one or more output terminals and positions of the detection points, based on information of the positions of the detection points and information of the detected one or more output currents at the one or more output terminals; and
determining from the correspondence relationship whether the detection points have a defect.

2. The failure detection method according to claim 1, wherein a charged particle beam is used as a detection current source to irradiate the detection points, and the charged particle beam is an electron beam or an ion beam.

3. The failure detection method according to claim 1, wherein a criterion for determining whether a detection point has a defect is: in the correspondence relationship, if a detection point is not at where the electrical conductor under test has a sudden change in shape or material, and if a corresponding output current at an output terminal varies irregularly with respect to a neighboring detection point, then a defect is present at the detection point or adjacent to the detection point.

4. A failure detection method for detecting a defect in a wire, including:
providing an output terminal at both ends of the wire, the output terminals having identical electric potentials;
inputting a constant detection current sequentially to detection points arranged on the wire along a predetermined path;
detecting an output current at one or both of the output terminals;
building a correspondence relationship between the detected one or both output currents at the one or both of the output terminals and positions of the detection points, based on information of the positions of the detection points and information of the detected one or both output currents at the one or both of the output terminals; and
determining from the correspondence relationship whether the detection points have a defect.

5. The failure detection method according to claim 4, wherein a charged particle beam with a constant energy is used as a detection current source to irradiate the detection points, and the charged particle beam is an electron beam or an ion beam.

6. The failure detection method according to claim 4, wherein a criterion for determining whether a detection point has a defect is: in the correspondence relationship, if an output current at an output terminal corresponding to a detection point varies irregularly with respect to a neighboring detection point, then a defect is present at the detection point or adjacent to the detection point.

7. The failure detection method according to claim 6, wherein the variation is a variation of the magnitude of an output current at any one of the output terminals versus the positions of the detection points.

8. The failure detection method according to claim 6, wherein the variation is a variation of a difference of output currents at both of the output terminals or the rate of change of the difference of output currents at both of the output terminals versus the positions of the detection points.

9. A failure detection apparatus, for detecting a defect in an electrical conductor under test, the electrical conductor being provided with at least two output terminals and the at least two output terminals having identical electric potentials, the failure detection apparatus comprising:
a detection current input module, adapted to input a detection current sequentially to detection points arranged on the electrical conductor under test along a predetermined path;
an output current detection module, adapted to detect an output current at one or more output terminals of the at least two output terminals; and
an analysis module, adapted to build a correspondence relationship between the detected one or more output currents at the one or more output terminals and positions of the detection points, based on information of the positions of the detection points and information of the detected one or more output currents at the one or more output terminals, to perform failure detection on the electrical conductor under test.

10. The failure detection apparatus according to claim 9, wherein the detection current input module comprises a charged particle beam generator adapted to generate a beam of charged particles to irradiate the electrical conductor under test.

11. The failure detection apparatus according to claim 10, further comprising:
a movement means, adapted to change a position where the electrical conductor under test is irradiated by the charged particle beam generator.

12. The failure detection apparatus according to claim 9, wherein the output current detection module comprises a current meter connected with an output terminal of the electrical conductor under test.
